(19) United States
(12) Patent Application Publication
(10) Pub. No.: US 2014/0097467 A1
(43) Pub. Date: Apr. 10, 2014

(54) COMPRESSIVELY STRAINED SOI SUBSTRATE

(71) Applicant: INTERNATIONAL BUSINESS MACHINES CORPORATION, (US)

(72) Inventors: Kangguo Cheng, Schenectady, NY (US); Bruce B. Doris, Brewster, NY (US); Ali Khakifirooz, Mountain View, CA (US); Ghavam Shahidi, Pound Ridge, NY (US)

(21) Appl. No.: 13/858,203

(22) Filed: Apr. 8, 2013

Related U.S. Application Data
(63) Continuation of application No. 13/647,862, filed on Oct. 9, 2012.

(51) Int. Cl. H01L 29/165

(52) U.S. Cl. CPC H01L 29/165
USPC 257/190

(57) ABSTRACT

A method of forming a strained silicon-on-insulator includes forming a first wafer having a compressively strained active semiconductor layer, forming a second wafer having an insulation layer formed above a bulk semiconductor layer, and bonding the compressively strained active semiconductor layer of the first wafer to the insulation layer of the second wafer.

### CROSS-REFERENCE TO RELATED APPLICATIONS AND PRIORITY CLAIM

This application is a continuation of U.S. Non-Provisional Application Ser. No. 13/647,862, entitled “COMPRESSIVELY STRAINED SOI SUBSTRATE”, filed Oct. 9, 2012, which is incorporated herein by reference in its entirety.

### BACKGROUND

The teachings described herein relate generally to silicon-on-insulator (SOI) semiconductor devices, and in particular, strained SOI semiconductor wafers.

Strained silicon (Si) has been adopted as a promising way to increase electron and hole mobility in semiconductor devices, such as SOI semiconductor wafers. A common approach to obtaining a strained Si device is to provide a stress liner to induce a tensile or compressive strain depending on the composition and deposition condition used to form the stress liner. Alternatively, embedded stressors such as SiGe or Si:C can be formed in the source and drain regions of the MOSFET to apply compressive or tensile strain to the channel, respectively. The embedded SiGe or Si:C layer, however, causes complications in fabrication processes such as, Si/SiGe intermixing, strain relaxation during device processing, and possible undesired effects on silicide formation. Moreover, as the desire for smaller-sized semiconductor wafers increases, there is less room available to accommodate embedded stressors or stress liners.

Strained silicon-on-insulator wafers, where the Si channel layer is made lattice-match to a relaxed SiGe template and thus is under tensile strain, provide an effective means to improve electron mobility. However, no method is known in the art to provide strained silicon-on-insulator with compressive strain.

### SUMMARY

According to an exemplary embodiment of the present teachings, a method of forming a strained silicon-on-insulator (SOI) substrate comprises forming a first wafer having a compressively strained active semiconductor layer, forming a second wafer having an insulation layer formed above a bulk semiconductor layer, and bonding the compressively strained active semiconductor layer to the insulation layer.

According to another exemplary embodiment of the present teachings, a method of forming a donor wafer comprises forming a relaxed semiconductor layer on a semiconductor substrate layer, and forming a compressively strained active semiconductor layer on an upper surface of the relaxed semiconductor layer to bond to an insulation layer of a handle wafer.

According to yet another exemplary embodiment of the present teachings, a method of forming a strained silicon layer on a semiconductor wafer comprises forming a relaxed layer including a semiconductor material having a first lattice constant on a substrate layer. The substrate layer includes a semiconductor material having a second lattice constant greater than the first lattice constant. The method further includes forming an etch stop layer having a third lattice constant on the relaxed semiconductor layer, and lattice matching the third lattice constant to the first lattice constant to induce a compressive strain upon the etch stop layer. The method further includes forming a compressively strained semiconductor layer having a fourth lattice constant being less than the first lattice constant on the etch stop layer, and lattice matching the fourth lattice constant to the first lattice constant to induce a compressive strain upon the compressively strained semiconductor layer.

Additional features and utilities are realized through the techniques of the present teachings. Other exemplary embodiments and utilities of the present teachings are described in detail herein. For a better understanding of the present teachings and corresponding features, detailed descriptions and drawings of exemplary embodiments and discussed below.

### BRIEF DESCRIPTION OF THE SEVERAL VIEWS OF THE DRAWINGS

The subject matter of the present teachings are particularly pointed out and distinctly claimed in the claims at the conclusion of the specification. The forgoing and other features, and utilities of the present teachings are apparent from the following detailed description taken in conjunction with the accompanying drawings in which:

FIG. 1 is a cross-sectional view of a donor wafer according to an exemplary embodiment of the present teachings;

FIG. 2 is a cross-sectional view of the donor wafer illustrated in FIG. 1 undergoing an implantation process according to an exemplary embodiment of the present teachings;

FIG. 3 is a cross-sectional view of the donor wafer illustrated in FIG. 2 bonded to a handle wafer according to an exemplary embodiment of the present teachings;

FIG. 4 is a cross-sectional view of the bonded donor-handle wafer undergoing a removal process according to an exemplary embodiment of the present teachings;

FIG. 5 is a cross-sectional view of the bonded donor-handle wafer illustrated in FIG. 4 undergoing an etching process according to an exemplary embodiment of the present teachings;

FIG. 6 is a cross-sectional view of a compressively strained silicon-on-insulator wafer according to an exemplary embodiment of the present teachings; and

FIGS. 7A-7B illustrate a flow diagram describing a method of fabricating a compressively strained silicon-on-insulator semiconductor substrate according to an exemplary embodiment of the present teachings.

### DETAILED DESCRIPTION

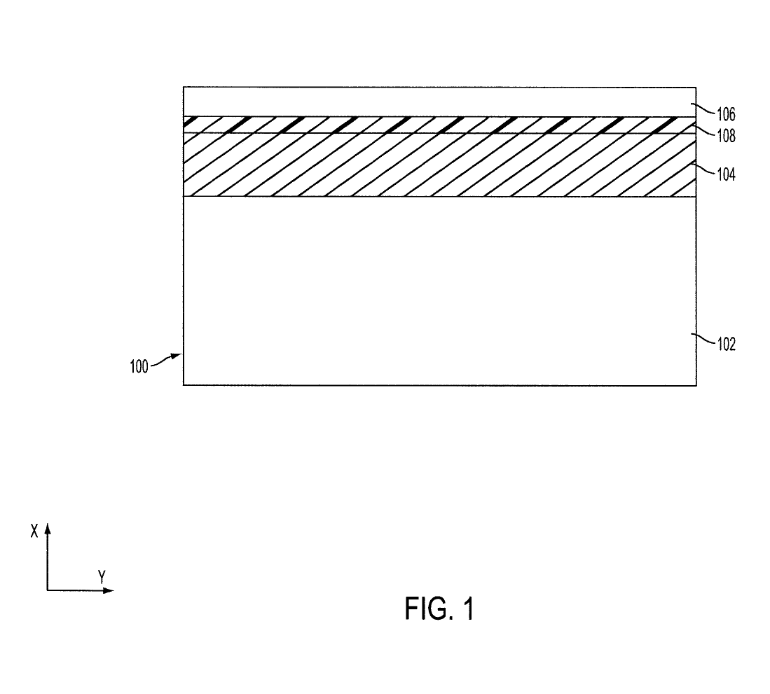

Referring now to FIG. 1, a donor wafer 100 is illustrated according to an exemplary embodiment of the present teachings. The donor wafer 100 may include a plurality of layers extending in an X-direction to define a thickness and a Y-direction to define a length. The plurality of layers included with the donor wafer 100 may be formed in a variety of well-known procedures including, but not limited to, epitaxial growth. The donor wafer 100 includes a bulk substrate layer 102, a relaxed layer 104 and a compressively strained layer 106. In at least one exemplary embodiment, the donor wafer 100 may include an auxiliary etch stop layer 108, disposed between the relaxed layer 104 and the compressively strained layer 106, which may assist in transferring the donor wafer 100 to a handle wafer, as discussed in greater detail below.

The bulk substrate layer 102 may be a relaxed substrate made of, for example, silicon (Si) having a first lattice structure corresponding to Si. The relaxed layer 104 is formed on the upper surface of the bulk substrate layer 102, and has a second lattice structure being smaller than the first lattice structure of the bulk substrate layer 102. In at least one exemplary embodiment, the relaxed layer 104 may be a relaxed carbon-doped silicon (Si:C) layer. The relaxed Si:C layer may be achieved in several ways. For example, a thick graded Si:C layer may be formed on the bulk substrate layer 102. In another example, strained Si:C may be grown on the bulk substrate layer 102, and then relaxed via well-known implantation and annealing processes. Further, the relaxed layer 104 has a thickness larger than the critical thickness of the material used in the relaxed layer 104. The critical thickness of the material used in the relaxed layer 104 may be determined using various methods including, but not limited to, the Matthews-Blakeslee Theory. Referring to the exemplary embodiment illustrated in FIG. 1, the critical thickness of the relaxed layer 104 corresponds to the thickness of the Si:C layer 104, and may further be based on the amount of carbon (C) included in the Si:C. In this case, for example, the thickness of the Si:C layer 104 ranges from about 40 nanometers (nm) to about 200 nm to ensure that the Si:C layer 104 may be fully relaxed.

As previously mentioned, at least one exemplary embodiment may include an auxiliary etch stop layer 108 formed on the Si:C layer 104 to assist in transferring the donor wafer 100 to a handle wafer. The auxiliary etch stop layer 108 may include a layer of silicon-germanium that is lattice matched the Si:C layer 104. Accordingly, the auxiliary etch stop layer 108 has a lattice constant that is smaller than the bulk substrate layer 102. For example, the exemplary embodiment illustrated in FIG. 1 illustrates a SiGe etch stop layer 108 formed on a relaxed Si:C layer 104, where the SiGe etch stop layer 108 is lattice matched to the relaxed Si:C layer 104. Accordingly, the SiGe etch stop layer 108 has a lattice constant that is smaller than the silicon substrate layer 102. Since SiGe has an equilibrium lattice constant larger than Si, the SiGe etch stop layer 108 is under compressive strain.

Further the thickness of the SiGe etch stop layer 108, i.e., extending in the X-axis directions, is thinner than the critical thickness of SiGe to prevent the SiGe etch stop layer 108 from relaxing. The critical thickness of the material used in the auxiliary etch stop layer 108 may be determined using various methods including, but not limited to, the Matthews-Blakeslee Theory. In at least one exemplary embodiment of the present teachings, the thickness of the SiGe etch stop layer 108 ranges from about 5 nm to about 25 nm. By preventing the SiGe etch stop layer 108 from relaxing, a final strained layer formed against an upper surface of the SiGe etch stop layer 108, which is discussed further below, is inhibited from lattice matching a relaxed SiGe etch stop layer 108 such that the final strain layer is prevented from exerting a tensile strain.

The compressively strained layer 106 is lattice matched to the relaxed layer 104, and therefore has a lattice constant that is smaller than the bulk substrate layer 102, i.e., the Si substrate. In at least one exemplary embodiment illustrated in FIG. 1, the compressively strained layer 106 is a compressively strained Si layer. Further, at least one exemplary embodiment illustrated in FIG. 1 includes forming the compressively strained layer 106, i.e., the compressively strained Si layer, on an upper surface of the auxiliary etch stop layer 108, i.e., the SiGe etch stop layer.

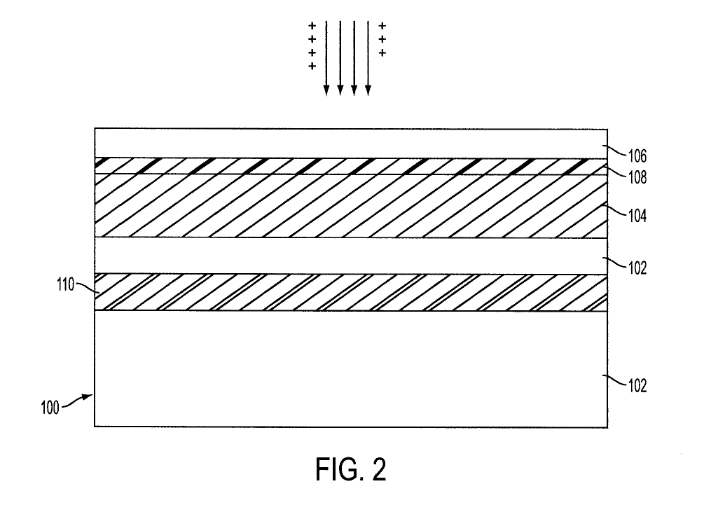

Referring to FIG. 2, the donor wafer 100 undergoes ion implantation and annealing processes, which are well-known in the art. Since the compressively strained layer 106 has a lattice contact that is smaller the lattice constant of the bulk substrate layer 102, i.e., the Si substrate layer, the ion implantation and annealing processes place the compressively strained layer 106, i.e., the compressively strained Si, into a compressed state. The ion implantation process includes implanting ions (+), for example hydrogen (H) or helium (He) ions at a predetermined depth in the bulk substrate layer 102. The annealing process may react with the ions and induce a damage region 110 in the bulk substrate layer 102, which may be removed according to well-known processes including, but not limited to, a smart-cut process, grinding, etc.

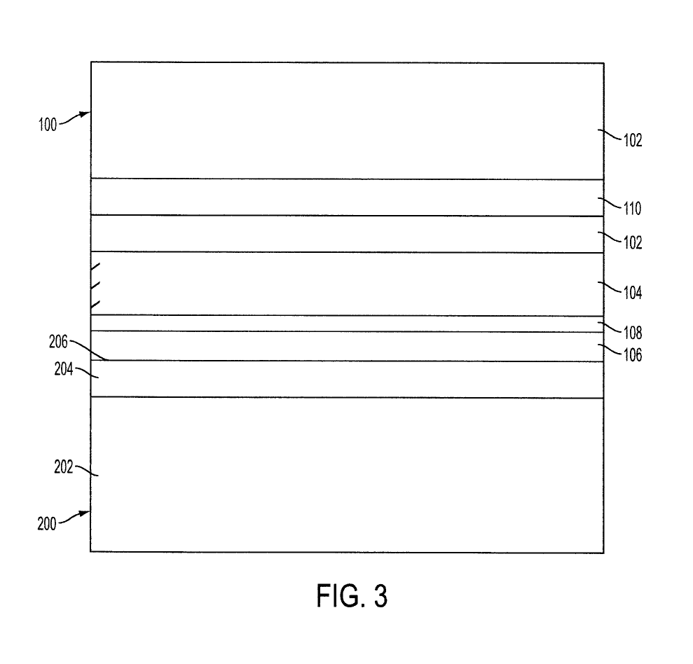

Referring now to FIG. 3, the donor wafer 100 is bonded to a handle wafer 200. The handle wafer 200 may include one or more layers extending in an X-direction to define a thickness and a Y-direction to define a length. Any well-known process for bonding the donor wafer 100 to the handle wafer 200 may be used including, but not limited to, a smart cut process. The handle wafer 200 includes a semiconductor layer 202 and an insulation layer 204. The handle wafer 200 may be made of any type of semiconductor material, such as silicon. With respect to the insulation layer 204, at least one exemplary embodiment described hereinafter utilizes an oxide (OX) layer including silicon oxide (SiO₂) as the insulator. It can be appreciated, however, that any dielectric may be used. According to at least one exemplary embodiment of the present teachings, the OX layer 204 has a thickness ranging from 5 nm to 175 nm.

A bonding point may be effected at a junction 206 of the compressively strained layer 106 and the insulation layer 204 in response to bonding the donor wafer 100 to the handle wafer 200. In at least one exemplary embodiment illustrated in FIG. 3, the compressively strained layer 106, i.e., the compressively strained Si layer, is bonded directly to the insulation layer 204, i.e., the OX layer.

In another embodiment, the insulator layer is formed on both the handle wafer and on top of the compressively strained layer of the donor wafer. And the bonding junction is formed at the interface of these two insulating layers.

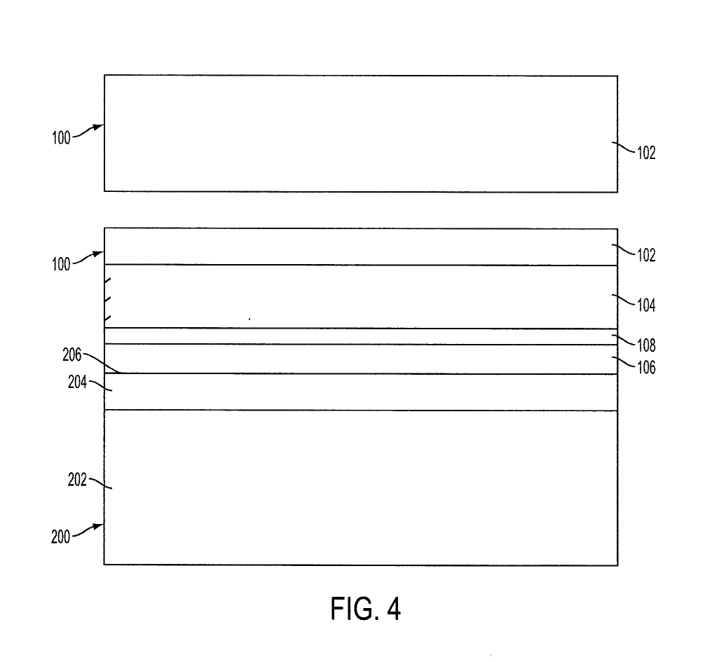

As illustrated in FIG. 4, the bulk substrate layer 102 and the damage region 110 may be removed from the donor wafer 100. At least one exemplary embodiment illustrated in FIG. 4 illustrates removing the bulk substrate layer 102 and the damage region 110 using a well-known smart-cut method. Alternatively, a grinding process may be used to remove the bulk substrate layer 102 and the damage region 110 from the donor wafer 100.

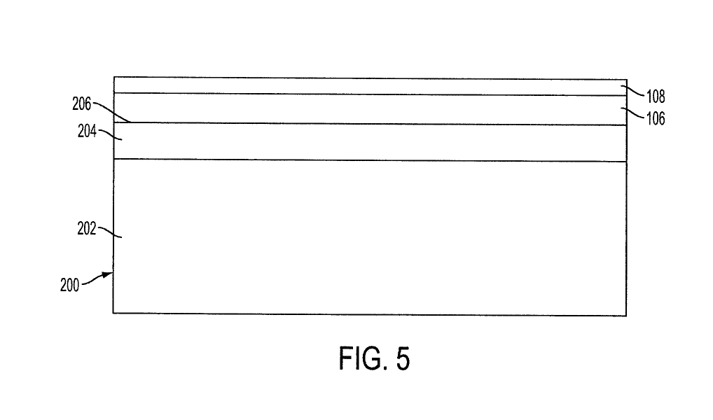

Referring now to FIG. 5, any residual portions of the bulk substrate layer 102′ and the relaxed layer 104, i.e., the Si:C layer, remaining from the donor wafer 100 may be removed using conventional removal process including, but not limited to, polishing, oxidation and wet etching. More specifically, the relaxed layer 104, i.e., the Si:C layer, may be selectively removed since the auxiliary etch stop layer 108 is made of durable material that withstands the removal process applied to the relaxed layer 104, and will therefore prevent etching from occurring therebeyond. Accordingly, after performing the removal of the relaxed layer 104, i.e., the Si:C layer, the auxiliary etch stop layer 108 and the compressively strained layer 106 are left formed on the insulator layer 204 of the handle wafer 200.

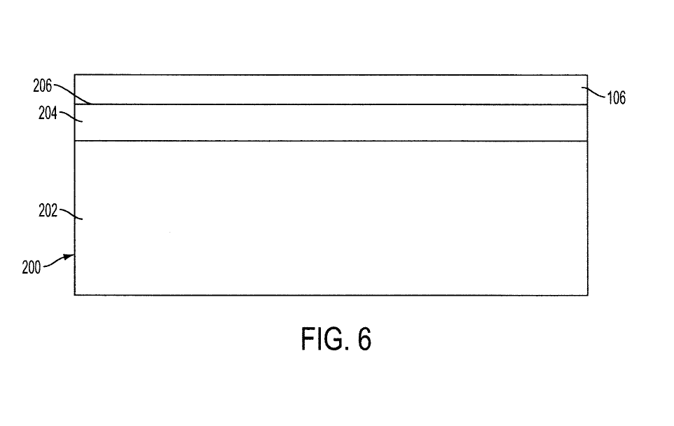

Referring now to FIG. 6, the auxiliary etch stop layer 108, i.e., the SiGe layer, may be selectively removed. The removal process applied to the etch sop layer 108, e.g., a second etching procedure such as etching in a hydrogen chloride (HCl)-containing ambient, or wet etching in a hydrogen peroxide (H₂O₂) containing mixture such an mixture of H₂O₂, NH₄OH and water, thereby leaving the compressively strained layer 106, i.e., the compressively strained Si layer, formed on the insulator layer 204, i.e., the OX layer. In other words, the final compressively strained Si layer 106 defines a compressively strained SOI layer, with the OX layer 204 serving as a buried oxide (BOX) layer that sits atop the semiconductor layer 202. At least one exemplary embodiment provides a final compressively strained Si layer 106 having a width of 1 nm to 50 nm. Further, the final compressively strained Si layer 106 may be placed under compressive biaxial strain. The force of compressive strain may be in a direction planar to the compressively strained Si layer 106. Accordingly, at least one exemplary embodiment illustrated in FIG. 6 provides a compressively strained silicon-on-insulator semiconductor wafer, which excludes any embedded stressor, e.g., an embedded SiGe stress layer, or compressive liner. Therefore, a compressively strained silicon-on-insulator (SSOI) may be provided that does not require additional accommodations for an embedded stressor.

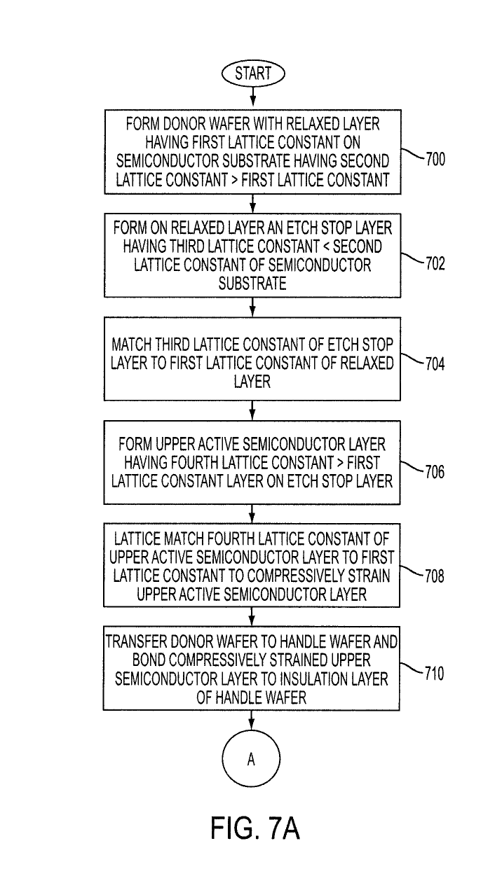

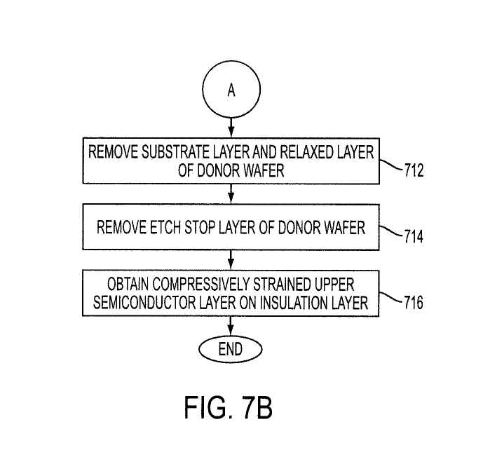

Referring now to FIGS. 7A-7B, a flowchart illustrates a method of fabricating a compressively strained upper active semiconductor layer on insulation semiconductor device according to an exemplary embodiment of the present teachings. In at least one exemplary embodiment, the compressively strained upper active semiconductor layer may be compressively strained silicon.

At operation 700, a donor wafer including a relaxed layer disposed on a semiconductor substrate layer is formed. The relaxed layer has a first lattice constant being smaller than a second lattice constant of the semiconductor substrate layer. In at least one exemplary embodiment the relaxed layer may comprise silicon carbon (Si:C), and the semiconductor substrate layer may comprise silicon (Si). At operation 702, an etch stop layer is formed on the relaxed layer. The etch stop layer has a third lattice constant that is less than the lattice constant of the second lattice constant of the semiconductor substrate layer. In at least one exemplary embodiment the etch stop layer may comprise silicon germanium (SiGe). Proceeding to operation 704, the etch stop layer is lattice matched with the relaxed layer, thereby inducing a compressive strain upon the etch stop layer. At operation 706, an upper active semiconductor layer is formed on the etch stop layer. The upper active semiconductor layer has a fourth lattice constant that is greater the first lattice constant of the relaxed layer, and thus also the third lattice constant of the etch stop layer. As discussed above, the upper active semiconductor layer may comprise Si. The upper active semiconductor layer is lattice matched to the relaxed layer and/or etch stop layer at operation 708. Since the upper active semiconductor layer has a lattice constant that is larger than the relaxed layer (and thus the etch stop layer), the upper active semiconductor layer realizes a compressive strain in response to being lattice matched to the relaxed layer and/or etch stop layer.

At operation 710, the donor wafer is transferred to a handle wafer. Various methods for transferring the donor wafer may be used including, but not limited to, a smart-cut process. In at least one exemplary embodiment, the compressively strained upper active semiconductor layer is bonded directly to an insulation layer of the handle wafer. The insulation layer may be, for example, a silicon oxide layer. Accordingly, a compressively strained silicon may be formed on an insulator. At operation 712, the semiconductor substrate layer and the relaxed layer included with the donor wafer may be removed using various methods including, but limited to, etching. The etch stop layer may also be removed at operation 714 using various methods, such as in a hydrogen chloride (HCl) containing ambient or a wet etching is a solution that contains hydrogen peroxide, such that compressively strained silicon-on-insulator (SSOI) may be obtained at operation 716 and the method ends.

The terminology used herein is for the purpose of describing particular embodiments only and is not intended to be limiting of the present teachings. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The description of the present teachings has been presented for purposes of illustration and description, but is not intended to be exhaustive or limited to the present teachings in the form disclosed. Many modifications and variations will be apparent to those of ordinary skill in the art without departing from the scope and spirit of the present teachings. The exemplary embodiment was chosen and described in order to best explain the principles of the present teachings and the practical application, and to enable others of ordinary skill in the art to understand the present teachings for various exemplary embodiments with various modifications as are suited to the particular use contemplated.

The flow diagrams depicted herein are just one example. There may be many variations to this diagram or operations described therein without departing from the spirit of the present teachings. For instance, the operations may be performed in a differing order or steps may be added, deleted or modified. All of these variations are considered a part of the claimed present teachings.

While exemplary embodiments of the present teachings have been described, it will be understood that those skilled in the art, both now and in the future, may make various improvements and enhancements which fall within the scope of the claims which follow. These claims should be construed to maintain the proper protection for the present teachings first described.

1. A strained silicon-on-insulator substrate, comprising:
a first wafer having a compressively strained active semiconductor layer, a relaxed silicon carbon (Si:C), and a compressed etch stop layer interposed between the compressively strained active semiconductor layer and the relaxed silicon carbon (Si:C) layer; and
a second wafer having an insulation layer formed above a bulk semiconductor layer, the insulation layer bonded directly to the compressively strained active semiconductor layer to the insulation layer,
wherein the compressively strained active semiconductor layer is silicon.

2. The strained silicon-on-insulator substrate of claim 1, wherein the first wafer further comprises a-the relaxed silicon carbon (Si:C) layer having a first lattice constant on a semiconductor substrate layer.

3. The strained silicon-on-insulator substrate of claim 2, wherein the semiconductor substrate layer has a second lattice constant greater than the first lattice constant of the relaxed silicon carbon (Si:C) layer.

4. The strained silicon-on-insulator substrate of claim 2, wherein the first wafer further comprises an etch stop layer formed on an upper surface of the relaxed semiconductor layer, the etch stop layer having a third lattice constant that is lattice matched to the first lattice constant of the relaxed silicon carbon (Si:C) layer.

5. The strained silicon-on-insulator substrate of claim 4, wherein the compressively strained active semiconductor layer is formed on the etch stop layer such that the compressively strained active semiconductor layer realizes a compressive strain in response to matching a lattice constant of the strained active semiconductor layer to the third lattice constant.

6. The strained silicon-on-insulator substrate of claim 4, wherein the compressively strained active layer is exposed in response to removing the bulk semiconductor layer, the relaxed silicon carbon (Si:C) layer and the etch stop layer.

7. The strained silicon-on-insulator substrate of claim 6, wherein the relaxed silicon carbon (Si:C) layer comprises silicon carbon (Si:C) and the semiconductor substrate layer comprises silicon.

8. The strained silicon-on-insulator substrate of claim 4, wherein the compressively strained active semiconductor layer is bonded to the insulation layer via a smart-cut process.

9. A donor wafer, comprising:
a relaxed semiconductor layer formed on a semiconductor substrate layer, the relaxed semiconductor layer formed from silicon carbon (Si:C); and
a compressively strained active semiconductor layer formed on an upper surface of the relaxed semiconductor layer to bond directly to an insulation layer of a handle wafer.

10. The donor wafer of claim 9, further comprising an etch stop layer formed on an upper surface of the relaxed semiconductor layer.

11. The donor wafer of claim 10, wherein the relaxed semiconductor layer has a first lattice constant that is smaller than a second lattice constant that the semiconductor substrate layer.

12. The donor wafer of claim 11, wherein the etch stop layer has a third lattice constant that is latticed matched to the first lattice constant of the relaxed semiconductor layer.

13. The donor wafer of claim 12, wherein the compressively strained active semiconductor layer has a fifth lattice constant that is lattice matched to the first lattice constant of the relaxed semiconductor layer such that the compressively strained active semiconductor layer exists in a compressively strained state.

14. The donor wafer of claim 13, wherein the relaxed semiconductor layer has first critical thickness and the etch stop layer comprises silicon germanium (SiGe) having a second critical thickness.

15. The donor wafer of claim 14, wherein a thickness of the relaxed semiconductor layer has a thickness greater than the first critical thickness and the etch stop layer has a thickness less than the second critical thickness.

16. A strained semiconductor wafer, comprising:
a substrate layer comprising a semiconductor material having a first lattice constant;
a relaxed semiconductor layer formed on the substrate layer, the relaxed semiconductor layer comprising a semiconductor material having a second lattice constant that is less than the first lattice constant of the substrate layer; and
an etch stop layer formed on the relaxed semiconductor layer, the etch stop layer having a third lattice constant that is lattice matched to the second lattice constant of the relaxed semiconductor layer to induce a compressive strain upon the etch stop layer; and
a compressively strained semiconductor layer formed on the etch stop layer, the compressively strained semiconductor layer having a fourth lattice constant that is less than third lattice constant, and that is lattice matched to the fourth lattice constant such that the compressively strained semiconductor layer exists in a compressively strained state,
wherein, the compressively strained semiconductor layer is silicon (Si), the etch stop layer is silicon germanium (SiGe), and the relaxed semiconductor layer is silicon carbon (SiC).

17. The strained semiconductor wafer of claim 16, wherein the substrate layer comprises silicon (Si),

18. The strained semiconductor wafer of claim 17, wherein a thickness of the relaxed semiconductor layer has a thickness greater than a critical thickness of silicon-carbon (Si:C) and the etch stop layer has a thickness less than a critical thickness of silicon germanium (SiGe).
